(19) United States
(12) Patent Application Publication
(10) Pub. No.: US 2024/0079216 A1
(43) Pub. Date: Mar. 7, 2024

(54) APPARATUS FOR TREATING SUBSTRATE AND METHOD FOR TREATING SUBSTRATE

(71) Applicant: PSK INC., Hwaseong-si (KR)

(72) Inventors: KWANG SUNG YOO, Hwaseong-si (KR); JONG CHAN LEE, Hwaseong-si (KR); TAE HOON KANG, Hwaseong-si (KR)

(21) Appl. No.: 18/462,379

(22) Filed: Sep. 6, 2023

(30) Foreign Application Priority Data
Sep. 7, 2022 (KR) 10-2022-0113707

(51) Int. Cl. H01J 37/32

(52) U.S. Cl. CPC H01J 37/32697; H01J 37/32568; H01J 37/32577; H01J 2237/334

(57) ABSTRACT

The inventive concept provides a substrate treating apparatus. The substrate treating apparatus includes a support plate for supporting a substrate and applying a power; a plasma control unit placed above the support plate to face the support plate; and a top electrode unit positioned to surround the plasma control unit, and wherein the plasma control unit includes: a dielectric plate positioned to face a top surface of a substrate mounted on the support plate; and a metal plate positioned above the dielectric plate, and the metal plate is electrically connected to the top electrode unit.

### CROSS-REFERENCE TO RELATED APPLICATIONS

A claim for priority under 35 U.S.C. § 119 is made to Korean Patent Application No. 10-2022-0113707 filed on Sep. 7, 2022, in the Korean Intellectual Property Office, the entire contents of which are hereby incorporated by reference.

### BACKGROUND

Embodiments of the inventive concept described herein relate to a substrate treating apparatus, more specifically a substrate treating apparatus for treating a substrate using a plasma.

A plasma refers to an ionized gas state made of ions, radicals, and electrons, and is produced by a very high temperature, a strong electric field, or a high-frequency electromagnetic field. A semiconductor element manufacturing process includes an ashing process or an etching process of removing a film on a substrate using the plasma. The ashing process or the etching process is performed by colliding or reacting with the film on the substrate by ions and radical particles contained in the plasma. Generally, components installed in a substrate treating apparatus using the plasma are fixedly installed within the apparatus. In particular, parts forming the electric field are fixed in their positions within the device, constantly maintaining a gap with the substrate according to a set recipe. It is difficult to change a characteristic of the electric field or the plasma without changing positions of the components forming the electric field.

### SUMMARY

Embodiments of the inventive concept provide a substrate treating apparatus and substrate treating method for efficiently treating a substrate.

Embodiments of the inventive concept provide a substrate treating apparatus and substrate treating method for effectively changing a characteristic of a plasma.

Embodiments of the inventive concept provide a substrate treating apparatus and substrate treating method for smoothly performing a maintenance work on a component exposed to a plasma.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a support plate for supporting a substrate and applying a power; a plasma control unit placed above the support plate to face the support plate; and a top electrode unit positioned to surround the plasma control unit, and wherein the plasma control unit includes: a dielectric plate positioned to face a top surface of a substrate mounted on the support plate; and a metal plate positioned above the dielectric plate, and the metal plate is electrically connected to the top electrode unit.

In an embodiment, the plasma control unit is configured in a plurality of sets, and while the plasma control unit is installed on the substrate treating apparatus, a total thickness between each set is the same while a thickness of the metal plate is different.

In an embodiment, while the plasma control unit is installed on the substrate treating apparatus, a gap between a bottom surface of the dielectric plate and a top surface of the support plate are constant, between each set.

In an embodiment, the plasma control unit is attachable/detachable to/from the top electrode unit.

In an embodiment, the substrate treating apparatus further includes: a housing having a treating space for treating the substrate; and a bottom edge electrode positioned below an edge region of the substrate mounted on the support plate, and wherein the top electrode unit includes: an electrode plate installed on a ceiling of the housing; and a top edge electrode coupled to a bottom end of an edge region of the electrode plate, and placed above the bottom edge electrode to face the bottom edge electrode, and the metal plate is coupled to a bottom end of a central region of the electrode plate.

In an embodiment, the metal plate is attachable/detachable to/from the electrode plate, and the dielectric plate is attachable/detachable to/from the metal plate.

In an embodiment, the electrode plate, the top edge electrode, and the metal plate are electrically connected to each other.

In an embodiment, while the plasma control unit is installed on the substrate treating apparatus, a gap between a bottom surface of the top edge electrode and a top surface of the bottom edge electrode are constant, between each set.

In an embodiment, when the power is applied to the support plate, an electric field is formed at the edge region of the substrate supported on the support plate by an electrical interaction between the support plate, the bottom edge electrode, the top edge electrode, the metal plate, and electrode plate.

The inventive concept provides a substrate treating apparatus. The substrate treating apparatus includes a housing having a treating space; a support unit positioned within the treating space; a gas supply unit configured to supply a gas excited to a plasma to the treating space; a plasma control unit positioned above the support unit to face the support unit and to change a characteristic of the plasma generated at the treating space; and a top electrode unit surrounding the plasma control unit, and wherein the top electrode unit includes: an electrode plate installed at a ceiling of the housing; and a top edge electrode coupled to a bottom end of an edge region of the electrode plate and electrically connected to the electrode plate, and wherein the plasma control unit includes: a metal plate coupled to a bottom end of a central region of the electrode plate and electrically connected to the electrode plate; and a dielectric plate coupled to a bottom side of the metal plate and positioned to face a central region of a substrate supported on the support unit, and wherein the support plate includes: a support plate to which a power is applied and which supports the substrate; and a bottom edge electrode surrounding the support plate and positioned below the top edge electrode to face the top edge electrode.

In an embodiment, the plasma control unit is configured in a plurality of sets, and while the plasma control unit is installed on the substrate treating apparatus, a thickness between each set is the same from a top surface of the metal plate to a bottom surface of the dielectric plate, while a thickness of the metal plate is different.

In an embodiment, while the plasma control unit is installed on the substrate treating apparatus, a gap between the bottom surface of the dielectric plate and a top surface of the support plate between each set are uniform.

In an embodiment, the plasma control unit can be attached/detached to/from the top electrode unit.

The inventive concept provides a substrate treating method. The substrate treating method includes a treating a substrate by generating a plasma at an edge region of a substrate supported on a support plate, and wherein the plasma is generated at the edge region due to an electrical interaction between a metal plate positioned above the support plate, a top edge electrode positioned above the edge region of the substrate, a bottom edge electrode positioned below the edge region, and the support plate to which a power is applied, and a characteristic of the plasma generated at the edge region is changed by changing a distance between the metal plate and the support plate.

In an embodiment, when the plasma is generated to treat the substrate, a distance between a top surface of the support plate and a bottom surface of a dielectric plate which is placed between the metal plate and the support plate to face the support plate is constantly maintained.

In an embodiment, the dielectric plate and the metal plate are defined as one set, a plurality of sets are configured, and the plurality of sets each have a total thickness from the bottom surface of the dielectric plate to the top surface of the metal surface which is constant, and a thickness of the metal plate is different.

In an embodiment, the metal plate is coupled to an electrode plate installed at a ceiling of a housing defining a space at which the plasma is generated, and the metal plate is attached/detached to/from the electrode plate to be changed to a metal plate having a different size.

In an embodiment, the dielectric plate is attachable/detachable to/from the metal plate.

In an embodiment, the metal plate is electrically connected to the electrode plate and the top edge electrode.

In an embodiment, when the plasma is generated to treat the substrate, a vertical distance between a bottom surface of the top edge electrode and a top surface of the bottom edge electrode is constantly maintained.

According to an embodiment of the inventive concept, a substrate may be efficiently treated.

According to an embodiment of the inventive concept, a characteristic of a plasma may be easily changed by replacing a plasma control unit which can be attached/detached to/from an apparatus.

According to an embodiment of the inventive concept, a maintenance work can be easily performed on a component exposed to a plasma.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a substrate treating apparatus according to an embodiment.

FIG. 2 is a cross-sectional view schematically illustrating treating a substrate using a plasma in the substrate treating apparatus according to an embodiment.

FIG. 3 is an enlarged view illustrating a first set of a plasma control unit according to an embodiment installed in the substrate treating apparatus.

FIG. 4 is an enlarged view illustrating a second set of a plasma control unit according to an embodiment installed in the substrate treating apparatus.

FIG. 5 is an enlarged view illustrating a third set of a plasma control unit according to an embodiment installed in the substrate treating apparatus.

FIG. 6 is an enlarged view illustrating a set of a plasma control unit installed in the substrate treating apparatus according to another embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

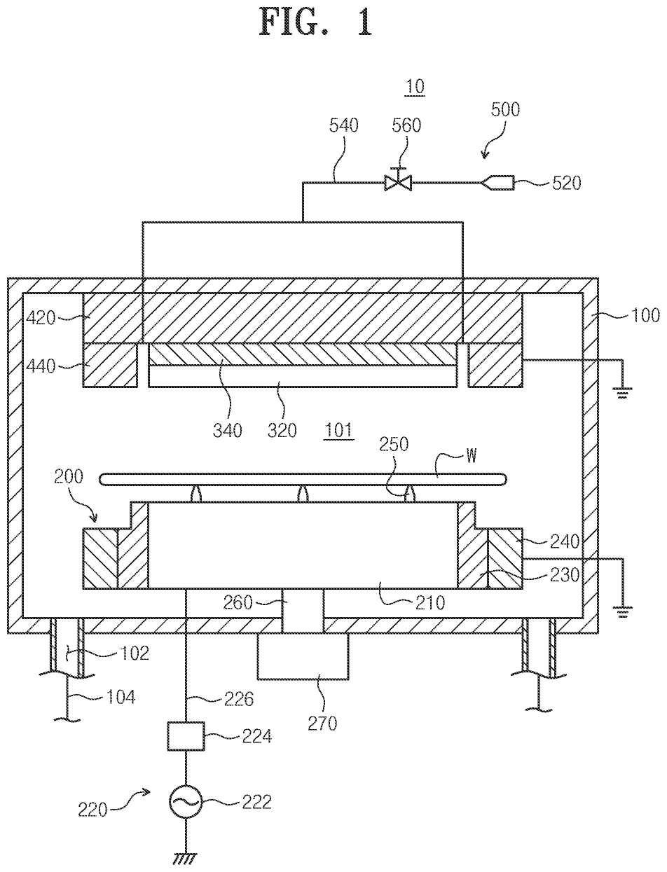

FIG. 1 is a cross-sectional view schematically illustrating a substrate treating apparatus according to an embodiment.

Hereinafter, the substrate treating apparatus 10 according to an embodiment of the inventive concept will be described in detail with reference to FIG. 1.

The substrate treating apparatus 10 performs a process treatment on a substrate W. The substrate treating apparatus 10 may perform a plasma treatment process on the substrate W. For example, the plasma treatment process performed in the substrate treating apparatus 10 may be an etching process which etches a film on the substrate W or an ashing process. The film may include various kinds of films such as a polysilicon film, an oxide film, a nitride film, a silicon oxide film, or a silicon nitride film. The oxide film described above may be a natural oxide film or a chemically generated oxide film. In addition, the film can be a foreign substance (byproduct) which occurs in a process of treating the substrate W to attach to and/or remains on the substrate W.

In the substrate treating apparatus 10 described below, a Bevel Etch process of removing a film existing on an edge region of the substrate W is described as an example. However, the inventive concept is not limited to this, and the substrate treating apparatus 10 described below can be applied equally or similarly to various processes in which the substrate W is treated using a plasma.

The substrate treating apparatus 10 may include a housing 100, a support unit 200, a plasma control unit 320 and 340, a top electrode unit 420 and 440, and a gas supply unit 500.

The housing 100 has a treating space 101 in which the substrate W is treated. The housing 100 may have a substantially hexahedral shape. A material of the housing 100 may include a metal. In addition, an inner surface of the housing 100 may be coated with an insulating material. The housing 100 is grounded.

An exhaust hole 102 is formed at a bottom of the housing 100. The exhaust hole 102 is connected to a exhaust line 104. A pump not shown is connected to the exhaust line 104. The pump (not shown) may be any one of known pumps which apply a negative pressure within the exhaust line 104. The pump (not shown) applies the negative pressure within the exhaust line 104 to control a pressure in the treating space 101, or exhaust impurities remaining or floating in the treating space 101.

An opening (not shown) is formed on a sidewall of the housing 100. The substrate W is taken into the treating space 101 or taken out of the treating space 101 through an opening (not shown). The opening (not shown) is opened or closed by an opening and closing device such as a door assembly (not shown). When the opening (not shown) is closed after the substrate W is taken into the treating space 101, an atmosphere of the treating space 101 can be created at a low pressure close to a vacuum by the pump (not shown).

The support unit 200 is positioned in the treating space 101. The support unit 200 supports the substrate in the treating space 101. The support unit 200 may include a support plate 210, a power supply unit 220, an insulation ring 230, and a bottom edge electrode 240.

The substrate W is mounted on a top surface of the support plate 210. Accordingly, the substrate W is supported by the support plate 210. The support plate 210 has a substantially circular shape when viewed from above. According to an embodiment, the support plate 210 may have a diameter smaller than that of the substrate W. Accordingly, a central region of the substrate W may be mounted on the top surface of the support plate 210, and an edge region of the substrate W may not contact the top surface of the support plate 210.

A temperature adjusting means (not shown) for adjusting a temperature of the support plate 210 may be disposed within the support plate 210. According to an embodiment, any one among the temperature control means (not shown) may be a heater which generates a heat by resisting a supplied current, and another of the temperature control means (not shown) may be a cooling fluid channel through which a cooled fluid flows. In addition, another of the temperature control means (not shown) may be a cooling plate for cooling the support plate 210.

The support plate 210 is coupled to a support shaft 260. The support shaft 260 is coupled to a bottom end of the support plate 210. The support shaft 260 has a vertical lengthwise direction. An end of the support shaft 260 is coupled to the support plate 210, and the other end thereof is connected to the driver 270. The driver 270 moves the support shaft 260 up and down. Accordingly, the support plate 210 and the substrate W supported by the support plate 210 may move in the top/down direction. The driver 270 may be any one of known motors such as a servo motor, a linear motor, or a pulse motor.

The power supply unit 220 applies a power to the support plate 210. The power supply unit 220 may include a power source 222, a matching device 224, and a power line 226. The power source 222 may be a bias power source for applying a bias voltage to the support plate 210. In addition, the power source 222 may be an RF power source which applies a high frequency voltage to the support plate 210. The power source 222 is electrically connected to the support plate 210 through the power line 226. The matching device 224 may be installed on the power line 226 to match an impedance.

The insulation ring 230 is disposed between the support plate 210 and the bottom edge electrode 240 to be described later. According to an embodiment, the insulation ring 230 may be made of an insulating material. Accordingly, the insulation ring 230 electrically separates the support plate 210 from the bottom edge electrode 240. The insulation ring 230 generally has a ring shape. The insulation ring 230 is disposed to surround the support plate 210. More specifically, the insulation ring 230 is disposed to surround an outer circumferential surface of the support plate 210.

According to an embodiment, a height of a top surface of an inner region of the insulation ring 230 and a height of a top surface of an outer region may be different. That is, the top surface of the insulation ring 230 may be formed to be stepped. For example, the insulation ring 230 may be stepped so that the height of the top surface of the inner region is higher than the height of the top surface of the outer region. When the substrate W is mounted on the support plate 210, the top surface of an inner region of the insulation ring 230 may contact a bottom surface of the substrate W. On the other hand, even if the substrate W is mounted on the support plate 210, the top surface of the outer region of the insulation ring 230 may be spaced apart from the bottom surface of the substrate W.

According to an embodiment, the bottom edge electrode 240 may be grounded. The material of the bottom edge electrode 240 includes a metal. The bottom edge electrode 240 generally has a ring shape. The bottom edge electrode 240 is disposed to surround an outer circumferential surface of the insulation ring 230. When viewed from above, the bottom edge electrode 240 is positioned in an edge region of the substrate W supported by the support plate 210. More specifically, the bottom edge electrode 240 is positioned below the edge region of the substrate W supported by the support plate 210.

A top surface of the bottom edge electrode 240 may be positioned at the same height as a top surface of an outer region of the insulation ring 230. In addition, the top surface of the bottom edge electrode 240 may be positioned at a lower height than the top surface of the support plate 210. Accordingly, the bottom edge electrode 240 may be spaced apart from the bottom surface of the substrate W supported by the support plate 210. Specifically, the top surface of the bottom edge electrode 240 and the bottom surface of the edge region of the substrate W supported by the support plate 210 may be spaced apart from each other. Accordingly, a plasma to be described later may penetrate a space between a bottom surface of the edge region of the substrate W and the top surface of the bottom edge electrode 240. In addition, the bottom surface of the bottom edge electrode 240 may be positioned at the same height as the bottom surface of the insulation ring 230.

A lift pin assembly (not shown) including a lift pin 250 may be disposed within the support plate 210. The lift pin 250 may be moved in the top/down direction by the driver (not shown) included in the lift pin assembly (not shown). The lift pin 250 may move in the top/down direction through a pin hole (not shown) formed in the support plate 210. A plurality of lift pins 250 may be provided. The plurality of lift pins 250 support the bottom surface of the substrate W at different positions, and the substrate W can be lifted/lowered by the lift pin 250 moving in the top/down direction.

The plasma control units 320 and 340 change a characteristic of a plasma generated in the treating space 101. More specifically, the plasma control units 320 and 340 change the characteristic of a plasma generated in the edge region of the substrate W supported by the support plate 210. A specific mechanism for changing the characteristic of the plasma generated in the edge region of the substrate W using the plasma control units 320 and 340 will be described later.

The plasma control units 320 and 340 are positioned within the treating space 101. The plasma control units 320 and 340 are positioned above the support plate 210. The plasma control units 320 and 340 are disposed to face the support plate 210. The plasma control units 320 and 340 are provided to be attachable/detachable from the top electrode units 420 and 440 to be described later. A detailed description of this will be described later.

The plasma control units 320 and 340 include a dielectric plate 320 and a metal plate 340. The dielectric plate 320 may be a disk-shaped dielectric substance. The dielectric plate 320 is disposed to face the support plate 310 positioned above the support plate 210. Accordingly, a bottom surface of the dielectric plate 320 faces the top surface of the support plate 210. The dielectric plate 320 is coupled to the metal plate 340. More specifically, the dielectric plate 320 is coupled to a bottom end of the metal plate 340. In addition, the dielectric plate 320 is provided attachable/detachable to the metal plate 340.

The metal plate 340 has a disk shape. The metal plate 340 may have a diameter corresponding to that of the dielectric plate 320. In addition, the metal plate 340 may share its center with the dielectric plate 320. The metal plate 340 may be coupled to an electrode plate 420 to be described later. More specifically, the metal plate 340 may be coupled to a bottom end of the electrode plate 420. The material of the metal plate 340 may include a metal. The metal plate 340 may be electrically connected to the electrode plate 420. In addition, the metal plate 340 is provided attachable/detachable to the electrode plate 420.

The top electrode units 420 and 440 are disposed within the treating space 101. In addition, the top electrode units 420 and 440 are disposed above the support unit 200. The top electrode units 420 and 440 are disposed to surround the plasma control units 320 and 340. More specifically, the top electrode units 420 and 440 may be disposed to surround side ends and top ends of the plasma control units 320 and 340.

The top electrode units 420 and 440 may include the electrode plate 420 and the top edge electrode 440.

The material of the electrode plate 420 includes a metal. According to an embodiment, the material of the electrode plate 420 may include an aluminum. The electrode plate 420 may be coupled to a ceiling of the housing 100. The electrode plate 420 may have a disk shape. According to an embodiment, a diameter of the electrode plate 420 may be greater than the diameters of the dielectric plate 320 and the metal plate 340. In addition, the electrode plate 420 may share its center with the dielectric plate 320 and the metal plate 340. The aforementioned metal plate 340 may be coupled to the bottom end of the electrode plate 420. In addition, the top edge electrode 440 is coupled to the bottom end of the electrode plate 420. Specifically, the metal plate 340 may be coupled to a bottom end of a central region of the electrode plate 420, and the top edge electrode 440 may be coupled to a bottom end of an edge region of the electrode plate 420. Accordingly, the electrode plate 420 may be electrically connected to the metal plate 340 and the top edge electrode 440.

The top edge electrode 440 may be grounded. The material of the top edge electrode 440 may include a metal. The top edge electrode 440 generally has a ring shape. The top edge electrode 440 is disposed to surround an outside of the plasma control units 320 and 340. More specifically, the top edge electrode 440 may be disposed to surround an outer circumferential surface of the dielectric plate 320 and an outer circumferential surface of the metal plate 340. In addition, an inner circumferential surface of the top edge electrode 440 may be spaced apart from the outer circumferential surface of the dielectric plate 320 and the outer circumferential surface of the metal plate 340 by a certain distance. A gas line 540 to be described later is connected to the separation space. A separation space overlaps the edge region of the substrate W when viewed from above. Accordingly, a gas supplied from the gas line 540 may be supplied to the edge region of the substrate W through the separation space.

In addition, the top edge electrode 440 is disposed above the edge region of the substrate W. In addition, the top edge electrode 440 is disposed to face the bottom edge electrode 240 while above the bottom edge electrode 240. Accordingly, when viewed from above, the top edge electrode 440 may overlap the edge region of the substrate W supported by the support plate 210.

The gas supply unit 500 supplies a gas to the treating space 101. The gas supplied to the treating space 101 may be a gas excited by a plasma. The gas supply unit 500 may include a gas source 520, a gas line 540, and a gas valve 560.

The gas source 520 stores a gas. The gas source 520 may be a known tank capable of storing a fluid. An end of the gas line 540 is connected to the gas source 520. In addition, the other end of the gas line 540 is connected to the above-described separation space. In addition, a gas valve 560 is installed in the gas line 540. The gas valve 560 may be an on/off valve and/or a flow control valve. The gas stored in the gas source 520 sequentially passes through the separation space from the gas line 540 and is supplied to the edge region of the substrate W.

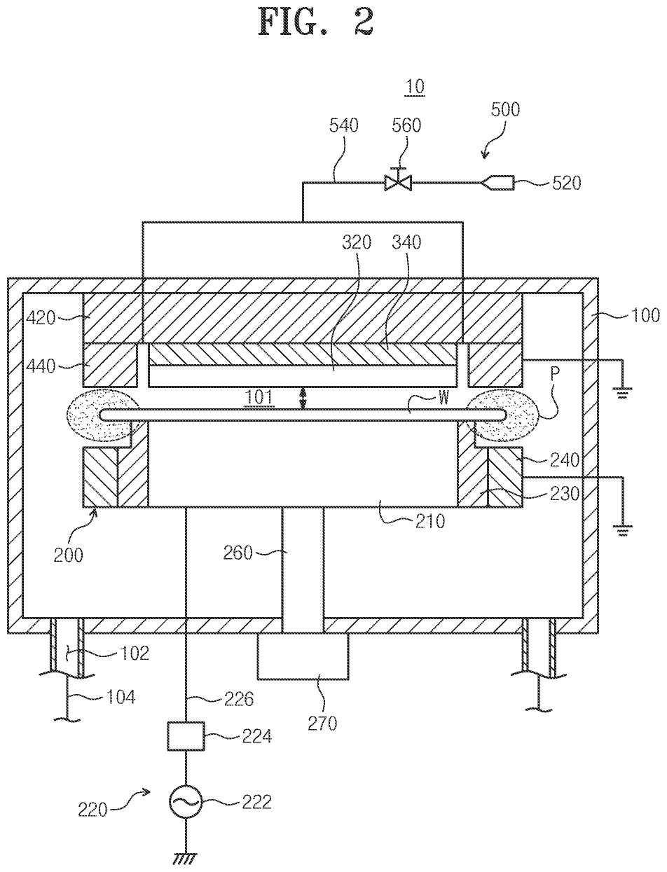

FIG. 2 is a cross-sectional view schematically illustrating treating a substrate using a plasma in the substrate treating apparatus according to an embodiment.

Referring to FIG. 2, the gas supply unit 500 supplies the gas to the edge region of the substrate W. The support plate 210 to which a high frequency power is applied or a bias power is applied, the grounded bottom edge electrode 240, the grounded top edge electrode 440, the electrode plate 420 electrically connected to the top edge electrode 440, and the metal plate 340 electrically connected to the electrode plate 420 electrically interact with each other to form an electronic field in the edge region of the substrate W.

The gas supplied to the edge region of the substrate W by the electric field formed in the edge region of the substrate W is excited to a plasma P state in the edge region of the substrate W. The plasma P formed in the edge region of the substrate W may etch the film formed in the edge region of the substrate W.

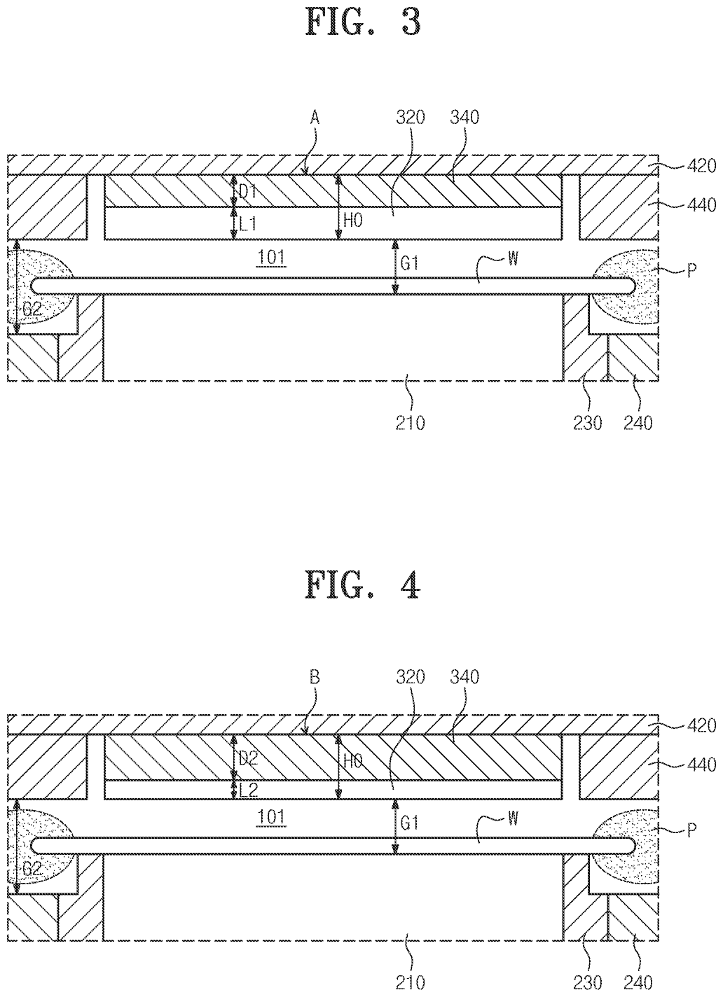

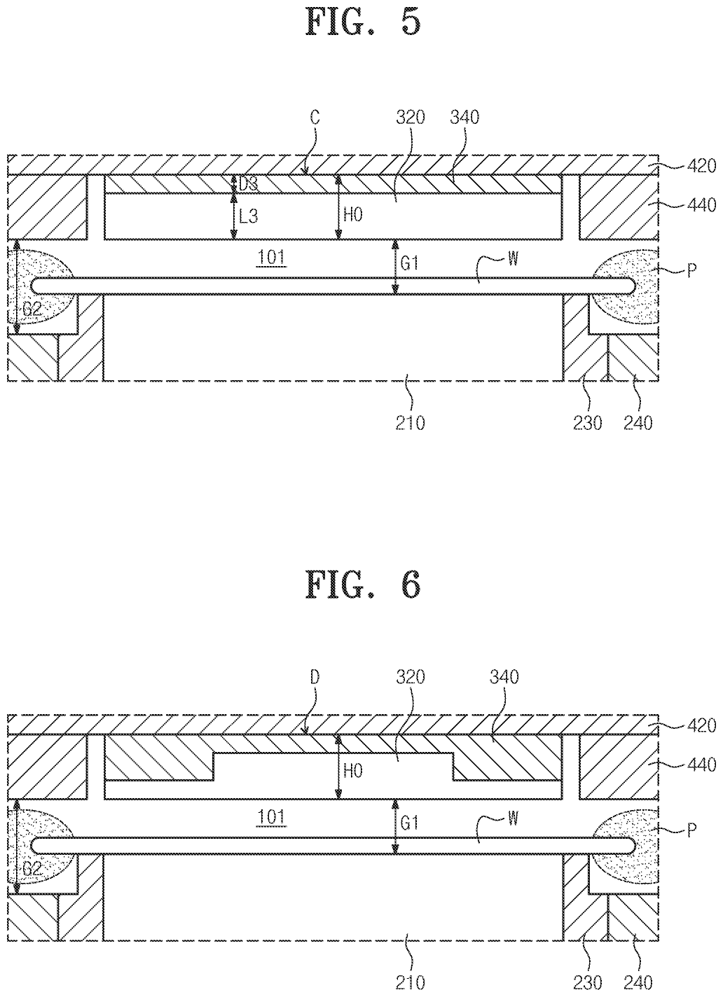

FIG. 3 is an enlarged view illustrating a first set of a plasma control unit according to an embodiment installed in the substrate treating apparatus. FIG. 4 is an enlarged view illustrating a second set of a plasma control unit according to an embodiment installed in the substrate treating apparatus. FIG. 5 is an enlarged view illustrating a third set of a plasma control units according to an embodiment installed in the substrate treating apparatus.

The plasma control units 320 and 340 may be provided in a plurality of sets. More specifically, the dielectric plate 320 and the metal plate 340 may be coupled to form a single set. A plurality of sets formed by coupling the dielectric plate 320 and the metal plate 340 may be provided. The plasma control units 320 and 340 may be provided as a first set A, a second set B, and a third set C. This is for convenience of understanding, and the embodiments of the inventive concept are not limited thereto.

As mentioned above, the dielectric plate 320 can be attached/detached to/from the metal plate 340, and the metal plate 340 can be attached/detached to/from the electrode plate 420. That is, the dielectric plate 320 among the metal plate 340 and the dielectric plate 320 constituting the first set A shown in FIG. 3 can be separated from the metal plate 340. Accordingly, only the dielectric plate 320 may be individually replaced.

In addition, the metal plate 340 constituting the first set A shown in FIG. 3 is separated from the electrode plate 420 so that the entire first set A may be separated from the substrate treating apparatus 10 (see FIG. 1). Accordingly, the first set A formed by combining the dielectric plate 320 and the metal plate 340 may be collectively replaced.

A mechanism by which the aforementioned dielectric plate 320 is attached/detached to/from the metal plate 340, and a mechanism by which the metal plate 340 is attached/detached to/from the electrode plate 420 is the same or similar in the second set B shown in FIG. 4 and the third set C shown in FIG. 5.

A total thickness between sets of a plurality of plasma control units 320 and 340 may be the same, but a thickness of the metal plate 340 may be different from each other.

In other words, between sets of the plurality of plasma control units 320 and 340, a height from the bottom surface of the dielectric plate 320 to the top surface of the metal plate 340 is the same. For example, a total thickness of the first set A, a total thickness of the second set B, and a total thickness of the third set C shown in FIG. 3 may all be HO. That is, the height from the bottom surface of the dielectric plate 320 to the top surface of the metal plate 340 constituting the first set A may be HO. In addition, the height from the bottom surface of the dielectric plate 320 to the top surface of the metal plate 340 constituting the second set B may be HO. In addition, the height from the bottom surface of the dielectric plate 320 to the top surface of the metal plate 340 constituting the third set C may be HO.

As described above, the thickness of each metal plate 340 constituting the first set A, the second set B, and the third set C is all different. For example, a thickness of the metal plate 340 constituting the first set A may be D1. In addition, a thickness of the metal plate 340 constituting the second set B may be D2. For example, D2 may be a value greater than D1. In addition, a thickness of the metal plate 340 constituting the third set C may be D3. For example, D3 may be less than D1 and D2.

As described above, since the total thickness of each set is the same, a thickness of the dielectric plate 320 constituting each set is also changed as a thickness of the metal plate 340 constituting each set is changed. For example, the thickness of the dielectric plate 320 constituting the first set A may be L1. In addition, the thickness of the dielectric plate 320 constituting the second set B may be L2. In addition, the thickness of the dielectric plate 320 constituting the third set C may be L3. For example, L3 may be greater than L1, and L1 may be greater than L2.

In addition, a sum of D1, the thickness of the metal plate 340 constituting the first set A, and L1, the thickness of the dielectric plate 320 constituting the first set A, may be HO. In addition, a sum of D2, the thickness of the metal plate 340 constituting the second set B, and L2, the thickness of the dielectric plate 320 constituting the second set B, may be HO. In addition, a sum of D3, the thickness of the metal plate 340 constituting the third set C, and L3, the thickness of the dielectric plate 320 constituting the third set C, may be HO. That is, the total thickness of each set is the same as HO, but the thickness of the metal plate 340 constituting each set may be different from each other.

According to an embodiment of the inventive concept described above, the thickness of the metal plate 340 can be changed by replacing each set in the substrate treating apparatus 10 (see FIG. 1). As the thickness of the metal plate 340 changes, the vertical distance between the metal plate 340 and the substrate W supported by the support plate 210 relatively changes. In addition, as the thickness of the metal plate 340 changes, the vertical distance between the metal plate 340 and the bottom edge electrode 240, the top edge electrode 440, and the electrode plate 420 relatively changes.

The metal plate 340 according to an embodiment induces a coupling of a bias power or a high-frequency power applied to the support plate 210 to contribute to changing a characteristic of the electric field or the plasma generated in the edge region of the substrate W. Accordingly, according to the above-described embodiment, since the thickness of the metal plate 340 is changed according to a selection of a plurality of sets, the characteristic of the electric field or the characteristic of the plasma generated in the edge region of the substrate W may be changed.

The gap between the bottom surface of the dielectric plate 320 and the top surface of the support plate 210 must be kept constant when forming the plasma P in the edge region of the substrate W. That is, while treating the substrate W using the plasma P, the vertical distance between the bottom surface of the dielectric plate 320 and the top surface of the support plate 210 should be maintained at the first reference distance G1 based on the recipe. In addition, while treating the substrate W using the plasma P, the vertical distance between the bottom surface of the top edge electrode 440 and the top surface of the bottom edge electrode 240 should be kept constant at the second reference distance G2 based on the recipe.

According to an embodiment of the inventive concept, since the total thickness of each set remains HO, the vertical distance between the bottom surface of the dielectric plate 320 and the top surface of the support plate 210 may be maintained at a first reference distance G1, even if a set with a different thickness of the metal plate 340 is installed at the substrate treating apparatus 10 (see FIG. 1). In addition, the vertical distance between the bottom surface of the top edge electrode 440 and the top surface of the bottom edge electrode 240 may be maintained at a second reference distance G2. Accordingly, it is possible to change a characteristic of the electric field or the plasma formed in the edge region of the substrate W based on a thickness change of the metal plate 340 without causing a change in the first reference distance G1 and the second reference distance G2 based on the recipe.

In addition, according to an embodiment of the inventive concept described above, each set may be simply separated from the substrate treating apparatus 10 (see FIG. 1) and another set may be simply installed in the substrate treating apparatus 10 (see FIG. 1). Accordingly, even with a simple replacement operation, the characteristic of the electric field or the characteristics of the plasma P formed in the edge region of the substrate W may be changed. In addition, according to the above embodiment, since the dielectric plate 320 can be attached/detached to/from the metal plate 340, the dielectric plate 320 with a relatively large frequency or area exposed to the electric field or the plasma can be easily maintained. In other words, if the dielectric plate 320 is damaged while performing the process, the dielectric plate 320 may be separated from the metal plate 340 and replaced with a new dielectric plate 320.

Hereinafter, a set of plasma control units according to another embodiment of the inventive concept will be described. Except for the additional description, since it is mostly the same or similar to the above-described embodiment, overlapping contents will be omitted.

FIG. 6 is an enlarged view illustrating a set of a plasma control unit installed in the substrate treating apparatus according to another embodiment.

Referring to FIG. 6, any portion of the plurality of sets may have a stepped top surface of the dielectric plate 320. For example, a central region of the top surface of the dielectric plate 320 can be formed in a stepped manner so that its height is higher than that of a top edge region of the dielectric plate 320. In addition, the bottom surface of the metal plate 340 may be formed stepped. The bottom surface of the metal plate 340 can be formed in a shape corresponding to the top surface of the dielectric plate 320 so as to be coupled to the top surface of the dielectric plate 320. For example, a central region of the bottom surface of the metal plate 340 may be stepped so as to be higher than the edge region.

In addition to the aforementioned embodiments, shapes of the dielectric plate 320 and the metal plate 340, which constitute a portion of the plurality of sets, can be variously modified. According to the aforementioned embodiment, the vertical distance between the bottom surface of the metal plate 340 and the top surface of the support plate 210 may be different for each region of the metal plate 340. Accordingly, characteristics of the electric field or characteristic of the plasma between the central region of the substrate W and the edge region of the substrate W may be finely controlled.

In the aforementioned example, it has been described as an example that both the bottom edge electrode 240 and the top edge electrode 440 are grounded, but the inventive concept is not limited thereto. For example, a high frequency power may be applied to any one of the bottom edge electrode 240 and the top edge electrode 440, and the other may be grounded. In addition, a high-frequency power may be applied to each of the bottom edge electrode 240 and the top edge electrode 440.

In addition, unlike the above example, the metal plate 340 may be electrically separated from the electrode plate 420 and may be grounded independently.

In addition to the above-described embodiments, although not shown, the gas supply unit 500 (see FIG. 1) may further supply the gas to the central region of the substrate. The gas supplied to the central region of the substrate may be a gas contributing to a formation of the plasma in the edge region of the substrate. In addition, the gas supplied to the central region of the substrate may be a carrier gas. In order to further supply the gas to the central region of the substrate, a gas fluid channel may be formed in the central region of the dielectric plate 320 and the central region of the metal plate 340.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a support plate for supporting a substrate and applying a power;
a plasma control unit placed above the support plate to face the support plate; and
a top electrode unit positioned to surround the plasma control unit, and
wherein the plasma control unit includes:
a dielectric plate positioned to face a top surface of a substrate mounted on the support plate; and
a metal plate positioned above the dielectric plate, and
the metal plate is electrically connected to the top electrode unit.

2. The substrate treating apparatus of claim 1, wherein the plasma control unit is configured in a plurality of sets, and
while the plasma control unit is installed on the substrate treating apparatus, a total thickness between each set is the same while a thickness of the metal plate is different.

3. The substrate treating apparatus of claim 2, wherein while the plasma control unit is installed on the substrate treating apparatus, a gap between a bottom surface of the dielectric plate and a top surface of the support plate are constant, between each set.

4. The substrate treating apparatus of claim 3, wherein the plasma control unit is attachable/detachable to/from the top electrode unit.

5. The substrate treating apparatus of claim 2, further comprising:
a housing having a treating space for treating the substrate; and
a bottom edge electrode positioned below an edge region of the substrate mounted on the support plate, and
wherein the top electrode unit includes:
an electrode plate installed on a ceiling of the housing; and
a top edge electrode coupled to a bottom end of an edge region of the electrode plate, and placed above the bottom edge electrode to face the bottom edge electrode, and
the metal plate is coupled to a bottom end of a central region of the electrode plate.

6. The substrate treating apparatus of claim 5, wherein the metal plate is attachable/detachable to/from the electrode plate, and
the dielectric plate is attachable/detachable to/from the metal plate.

7. The substrate treating apparatus of claim 5, wherein the electrode plate, the top edge electrode, and the metal plate are electrically connected to each other.

8. The substrate treating apparatus of claim 5, wherein while the plasma control unit is installed on the substrate treating apparatus, a gap between a bottom surface of the top edge electrode and a top surface of the bottom edge electrode are constant, between each set.

9. The substrate treating apparatus of claim 5, wherein when the power is applied to the support plate, an electric field is formed at the edge region of the substrate supported on the support plate by an electrical interaction between the support plate, the bottom edge electrode, the top edge electrode, the metal plate, and electrode plate.

10. A substrate treating apparatus comprising:
a housing having a treating space;
a support unit positioned within the treating space;
a gas supply unit configured to supply a gas excited to a plasma to the treating space;
a plasma control unit positioned above the support unit to face the support unit and to change a characteristic of the plasma generated at the treating space; and
a top electrode unit surrounding the plasma control unit, and
wherein the top electrode unit includes:
an electrode plate installed at a ceiling of the housing; and
a top edge electrode coupled to a bottom end of an edge region of the electrode plate and electrically connected to the electrode plate, and
wherein the plasma control unit includes:
a metal plate coupled to a bottom end of a central region of the electrode plate and electrically connected to the electrode plate; and
a dielectric plate coupled to a bottom side of the metal plate and positioned to face a central region of a substrate supported on the support unit, and
wherein the support plate includes:
a support plate to which a power is applied and which supports the substrate; and
a bottom edge electrode surrounding the support plate and positioned below the top edge electrode to face the top edge electrode.

11. The substrate treating apparatus of claim 10, wherein the plasma control unit is configured in a plurality of sets, and
while the plasma control unit is installed on the substrate treating apparatus, a thickness between each set is the same from a top surface of the metal plate to a bottom surface of the dielectric plate, while a thickness of the metal plate is different.

12. The substrate treating apparatus of claim 11, wherein while the plasma control unit is installed on the substrate treating apparatus, a gap between the bottom surface of the dielectric plate and a top surface of the support plate between each set are uniform.

13. The substrate treating apparatus of claim 12, wherein the plasma control unit can be attached/detached to/from the top electrode unit.

14. A substrate treating method comprising:
treating a substrate by generating a plasma at an edge region of a substrate supported on a support plate, and
wherein the plasma is generated at the edge region due to an electrical interaction between a metal plate positioned above the support plate, a top edge electrode positioned above the edge region of the substrate, a bottom edge electrode positioned below the edge region, and the support plate to which a power is applied, and
a characteristic of the plasma generated at the edge region is changed by changing a distance between the metal plate and the support plate.

15. The substrate treating method of claim 14, wherein when the plasma is generated to treat the substrate, a distance between a top surface of the support plate and a bottom surface of a dielectric plate which is placed between the metal plate and the support plate to face the support plate is constantly maintained.

16. The substrate treating method of claim 15, wherein the dielectric plate and the metal plate are defined as one set, a plurality of sets are configured, and the plurality of sets each have a total thickness from the bottom surface of the dielectric plate to the top surface of the metal surface which is constant, and a thickness of the metal plate is different.

17. The substrate treating method of claim 16, wherein the metal plate is coupled to an electrode plate installed at a ceiling of a housing defining a space at which the plasma is generated, and the metal plate is attached/detached to/from the electrode plate to be changed to a metal plate having a different size.

18. The substrate treating method of claim 16, wherein the dielectric plate is attachable/detachable to/from the metal plate.

19. The substrate treating method of claim 17, wherein the metal plate is electrically connected to the electrode plate and the top edge electrode.

20. The substrate treating method of claim 14, wherein when the plasma is generated to treat the substrate, a vertical distance between a bottom surface of the top edge electrode and a top surface of the bottom edge electrode is constantly maintained.
